(19) United States
(12) Patent Application Publication
(10) Pub. No.: US 2025/0377378 A1
(43) Pub. Date: Dec. 11, 2025

(54) AUTOMATED SOCKET ACTUATION OF A SEMICONDUCTOR DEVICE PROGRAMMER

(71) Applicant: BMP Microsystems, Inc., Houston, TX (US)

(72) Inventors: William H. White, Cypress, TX (US); Srikar Reddy Bhimavarapu, Houston, TX (US); Rishav Kumar Dokania, Houston, TX (US); Rujuta Manan Mehta, Richmond, TX (US); Douglas W. Morris, Houston, TX (US); James McCormick, Crosby, TX (US)

(21) Appl. No.: 19/232,345

(22) Filed: Jun. 9, 2025

Related U.S. Application Data
(60) Provisional application No. 63/657,477, filed on Jun. 7, 2024.

(51) Int. Cl. G01R 1/04

(52) U.S. Cl. CPC G01R 1/0458; G01R 1/0466

(57) ABSTRACT

An automated socket actuation device may include a pressure plate configured to contact at least one socket. The device may include at least one actuator configured to cause the pressure plate to press down on the at least one socket. The device may further include a lid movable between an open position and a closed position. The device may inhibit operation of the at least one actuator when the lid is not in the closed position.

### CROSS-REFERENCED TO RELATED APPLICATION

This application claims priority to U.S. Provisional Application No. 63/657,477, which was filed on Jun. 7, 2024.

### BACKGROUND

In an electronics manufacturing facility, technicians may program thousands of devices in a single shift using a manual device programmer. The process requires the technician to load these devices in batches of 1 to 16. Each device needs to be carefully placed into a socket, which involved pressing hard, up to 10 lbs, on a tiny spring-loaded socket to open it. The socket must be held down while inserting each device. A start button is then pressed to initiate programming.

Once programmed, each device is unloaded with the same challenging mechanism, i.e. holding down the spring-loaded socket. The repetitive strain of pressing the sockets open may cause fatigue and injuries. High-force sockets may even require two operators, further increasing the complexity and time required for each task.

### SUMMARY

An automated socket actuation device programmer minimizes operator fatigue and improves efficiency and productivity. This innovative machine automates the strenuous task of opening and closing the sockets, allowing an operator to focus solely on loading and unloading a batch of devices into pre-opened sockets. A protective lid cover with tamper-proof sensors eliminates risk of finger pinching. This also streamlines the workflow by automatically starting the programming when the lid is closed. This eliminates the need for a manual start push button. This new system significantly improves efficiency, throughput and prevents repetitive motion injuries. The pre-opened sockets actuated by dual motors reduce placement errors and damaged devices, while the automation reduces the skill level required for operation. For high-force sockets, the need for two operators is eliminated, allowing a single technician to manage the process independently. Additionally, this opens up the possibility to use higher density and high force sockets, which are not possible to open manually, allowing more sockets in a programmer and further enhancing productivity.

In some aspects, the techniques described herein relate to a socket actuation device including: a pressure plate configured to contact at least one socket; and at least one actuator configured to cause the pressure plate to press down on the at least one socket.

In some aspects, the techniques described herein relate to a socket actuation device wherein the pressure plate includes a plurality of bar portions defining a plurality of elongated openings through which devices can be placed into sites in the at least one socket.

In some aspects, the techniques described herein relate to a socket actuation device further including a lid movable between an open position in which the at least one socket can be accessed by a user and a closed position preventing access to the at least one socket by the user.

In some aspects, the techniques described herein relate to a socket actuation device further including at least one switch configured to inhibit the at least one actuator when the lid is not in the closed position.

In some aspects, the techniques described herein relate to a socket actuation device wherein the at least one switch includes a photoelectric sensor.

In some aspects, the techniques described herein relate to a socket actuation device wherein the at least one switch further includes a miniature switch.

In some aspects, the techniques described herein relate to a socket actuation device wherein the at least one switch further includes a relay connected to the miniature switch and wherein the relay disconnects the at least one actuator from power based upon a state of the miniature switch.

In some aspects, the techniques described herein relate to a socket actuation device wherein the at least one actuator is stopped if either the miniature switch or the photoelectric sensor indicates that the lid is not in the closed position.

In some aspects, the techniques described herein relate to a socket actuation device wherein the at least one actuator includes at least one electric motor.

In some aspects, the techniques described herein relate to a socket actuation device wherein the at least one electric motor includes a threaded shaft, wherein rotation of the threaded shaft moves the pressure plate.

In some aspects, the techniques described herein relate to a method for programming at least one device including: a) pressing at least one socket in a first direction with a pressure plate; b) after step a), receiving a device in each of at least one site in the at least one socket; c) after step b), moving the pressure plate in a second direction, opposite the first direction; d) after step c), programming the device in each site in the at least one socket; and e) after step d), moving the pressure plate in the first direction to open the at least one socket.

In some aspects, the techniques described herein relate to a method wherein step a) includes activating at least one actuator.

In some aspects, the techniques described herein relate to a method wherein step a) includes activating at least one electric motor having a threaded shaft engaging the pressure plate.

In some aspects, the techniques described herein relate to a method further including: f) receiving an indication that a lid is in a closed position; wherein the lid prevents a user from accessing the at least one socket when the lid is in the closed position and permits a user to access the at least one socket when the lid is in an open position, wherein step a) is performed based upon step f).

In some aspects, the techniques described herein relate to a method wherein step f) includes receiving a signal from a photoelectric sensor and receiving a signal from a contact switch.

In some aspects, the techniques described herein relate to a method further including: f) after step e), removing the device from each of the at least one site in the at least one socket.

In some aspects, the techniques described herein relate to a socket actuation device including: a housing having a bottom plate, a side plate secured to the bottom plate, and a top plate secured to the side plate; at least one motor within the housing, each at least one motor including a threaded shaft extending upward through the top plate; a programmer site secured to the top plate; a pressure plate secured to the programmer site and configured to contact at least one socket, each threaded shaft threadably engaging the pressure plate; and a lid pivotably secured to the housing and pivotable between a closed position in which access to the programmer site is prevented and an open position in which access to the programmer site is permitted.

In some aspects, the techniques described herein relate to a socket actuation device wherein the pressure plate includes a plurality of bar portions defining a plurality of elongated openings through which devices can be placed into sites in the at least one socket.

In some aspects, the techniques described herein relate to a socket actuation device further including at least one switch configured to inhibit the at least one motor when the lid is not in the closed position.

In some aspects, the techniques described herein relate to a socket actuation device wherein the at least one switch includes a photoelectric sensor and a contact switch, wherein the at least one motor is inhibited if either the contact switch or the photoelectric sensor indicates that the lid is not in the closed position.

### BRIEF DESCRIPTION OF THE DRAWINGS

FIG. 1 is an exploded view of an automated socket actuation device.

FIG. 2 is an enlarged view of the lid, hinge bracket and hinges of FIG. 1.

FIG. 3 is an enlarged exploded view of the top plate and the pressure plate.

FIG. 4 is a perspective view of the pressure plate.

FIG. 5 is a perspective view of one of the T-posts.

FIG. 6 is a rear perspective view of the lid connected to the side plate.

FIG. 7 is a rear view of the lid and side plate of FIG. 6.

FIG. 8 is an exploded view of the top plate and pressure plate with a plurality of sockets installed on the programmer site.

FIG. 9 is an assembled view of the components of FIG. 8.

FIG. 10 is a side view of the assembly of FIG. 9.

FIG. 11 is an end view of a partial assembly of the pressure plate secured to the T-post.

FIG. 12 is an enlarged exploded view of the top plate and the pressure plate with devices in the sockets.

FIG. 13 is a perspective front view of the assembled automated socket actuation device with the lid in the open position.

FIG. 14 is a schematic of the operation of the automated socket actuation device.

FIG. 15 is a higher-level flowchart emphasizing the user's operations versus steps performed by the automated socket actuation device.

### DETAILED DESCRIPTION

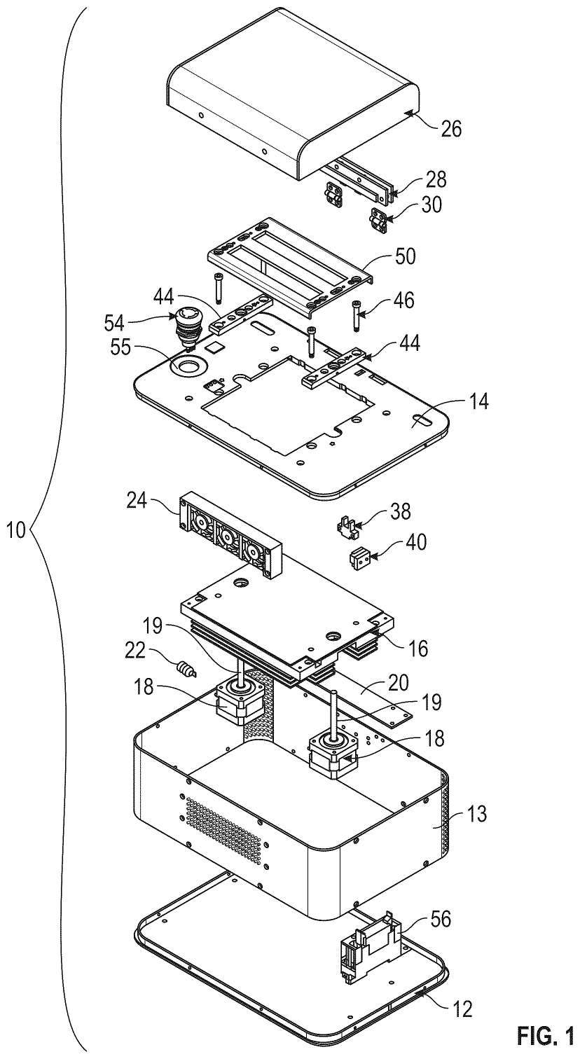

An exploded view of an automated socket actuation device 10 is shown in FIG. 1. The automated socket actuation device 10 includes a bottom plate 12, which is securable to a housing side plate 13, which in turn is securable to a top plate 14. The housing side plate 13 extends about the periphery of the bottom plate 12. A programmer site 16 is securable to the top plate 14 and includes a power supply, a motherboard, and appropriate mounting hardware (not shown), as is known.

At least one motor 18 (and preferably a plurality of motors 18) is receivable within the housing formed by the top plate 14, bottom plate 12, and housing side plate 13. Each motor 18 includes a shaft 19 that can be received in an aperture through the programmer site 16 and an aperture through the top plate 14.

A PCB 20 for sensors (as will be explained) may also be mounted within the housing. A ground connector 22 is securable to the housing and may also be connected to a wrist strap in order to ground a user, as is known. A plurality of fans 24 may be mounted in the housing to cool the programmer site 16.

A lid 26 is connectable to the side plate 13 via a hinge bracket 28 and hinges 30. The lid 26 may be translucent plastic, such as polycarbonate. As will be explained later, the lid 26 interacts with two sensors, a photoelectric sensor 38 and a miniature switch 40 (such as a contact switch), which provide a redundant indication of whether the lid 26 is open or closed.

The automated socket actuation device 10 includes at least one T-post 44 and in this example a plurality of T-posts 44. Each T-post 44 slidably receives at least one guide 46. In this example, each T-post 44 slidably receives two guides 46, which in this example are shoulder bolts that can be threaded into the top plate 14. The guides 46 limit the T-posts 44 to straight vertical movement up and down and limit the upward travel of the T-posts 44. Each T-post 44 is securable to a pressure plate 50.

An emergency stop button 54 may be mountable within an aperture 55 through to the top plate 14. A safety relay 56 is received within the housing.

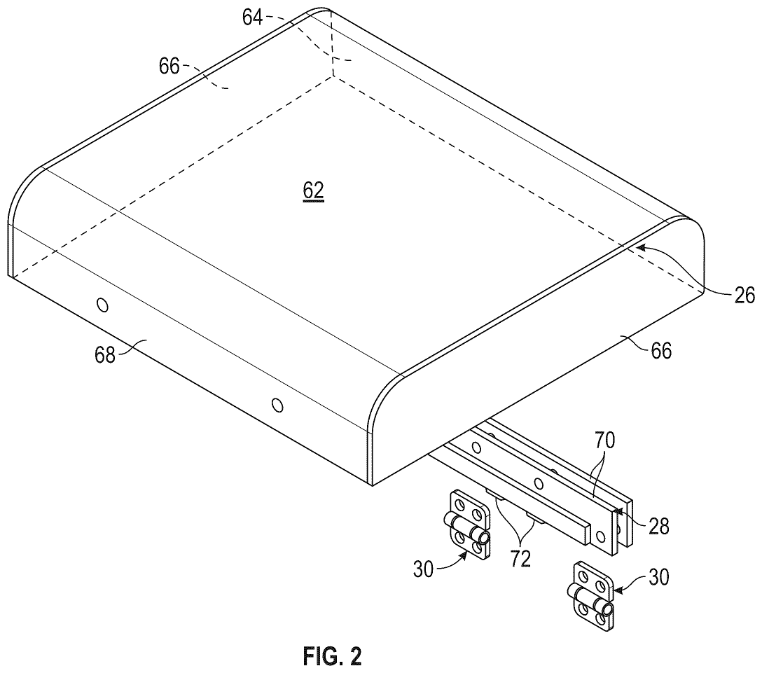

FIG. 2 is an enlarged view of the lid 26, hinge bracket 28 and hinges 30 of FIG. 1. The lid 26 may include a recessed underside defined by an upper wall 62, with a rear wall 64, side walls 66, and a front wall 68 extending downward from a periphery of the upper wall 62.

The hinge bracket 28 is securable to the rear wall 64. The hinge bracket 28 includes a pair of spaced-apart hinge plates 70 that are configured to secure a portion of the rear wall 64 therebetween. A pair of projections 72 project downward from the hinge bracket 28. The pair of hinges 30 are securable to the hinge bracket 28 and to the side plate 13 (FIG. 1).

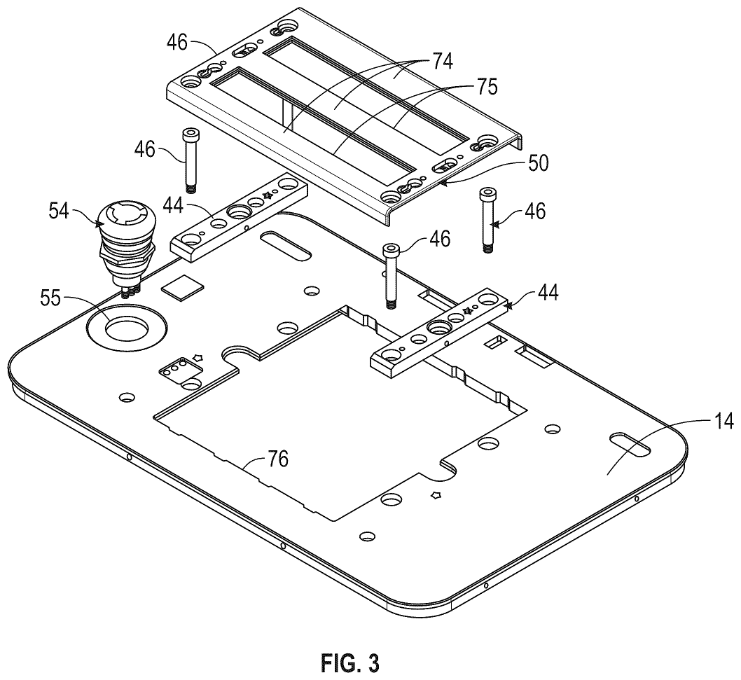

FIG. 3 is an enlarged exploded view of the top plate 14 and the pressure plate 50. The pressure plate 50 includes a plurality of bar portions 74 and elongated openings 75 between the plurality of bar portions 74. The bar portions 74 and elongated openings 75 are configured such that the bar portions 74 will engage the face (or bearing surfaces) of a socket while the elongated openings 75 will align with and provide access to place and remove the devices from the sites in the sockets. A large opening 76 is formed through the top plate 14 and aligned below the pressure plate 50.

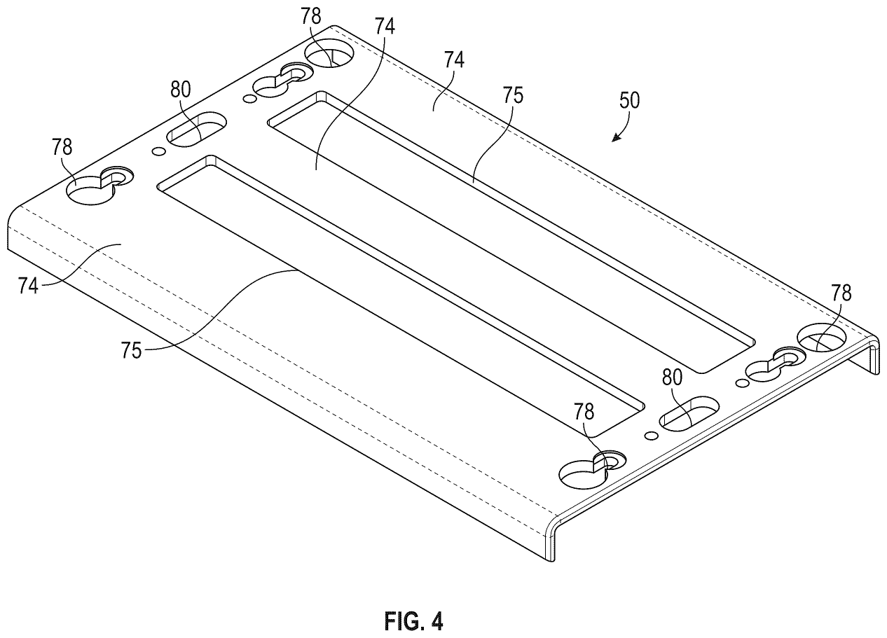

FIG. 4 is a perspective view of the pressure plate 50. Although only two elongated openings 75 and three bar portions 74 are shown, the pressure plate 50 could have more or fewer depending on the number and configurations of the sockets being actuated.

Each end of the pressure plate 50 includes a plurality of apertures, including a pair of guide apertures 78 for receiving the guides 46. The pressure plate 50 also includes apertures 80 each configured to receive the shaft 19 of one of the motors 18 therethrough without engagement. Other apertures may be used to secure the pressure plate 50 to the T-posts 44.

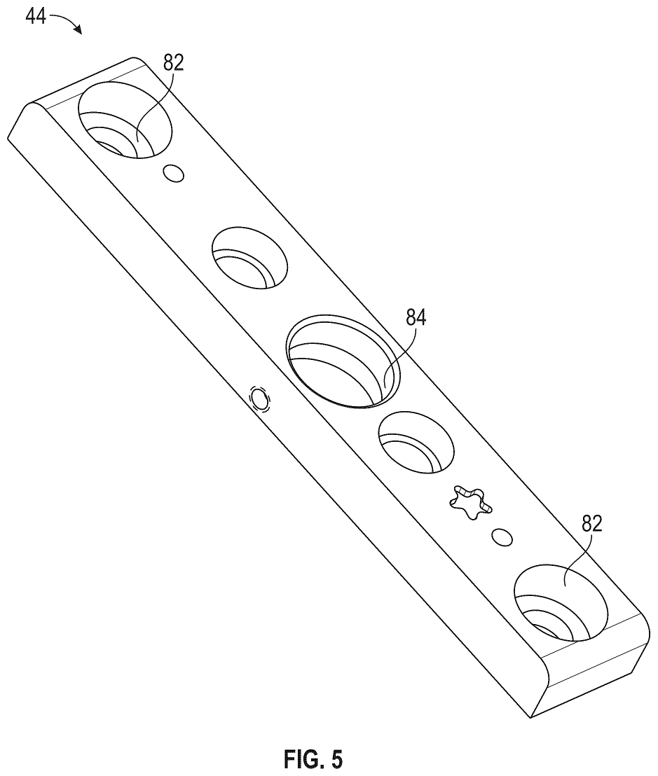

FIG. 5 is a perspective view of one of the T-posts 44. The T-post 44 is an elongated bar having a plurality of apertures formed therethrough, including a pair of countersunk apertures 82 with shoulders configured to engage the heads of the guides 46, which are shoulder bolts, such that the heads of the shoulder bolts do not pass through the countersunk apertures 82. The T-post 44 also includes a threaded aperture 84 for engaging threads on the shaft 19 of the at least one motor 18.

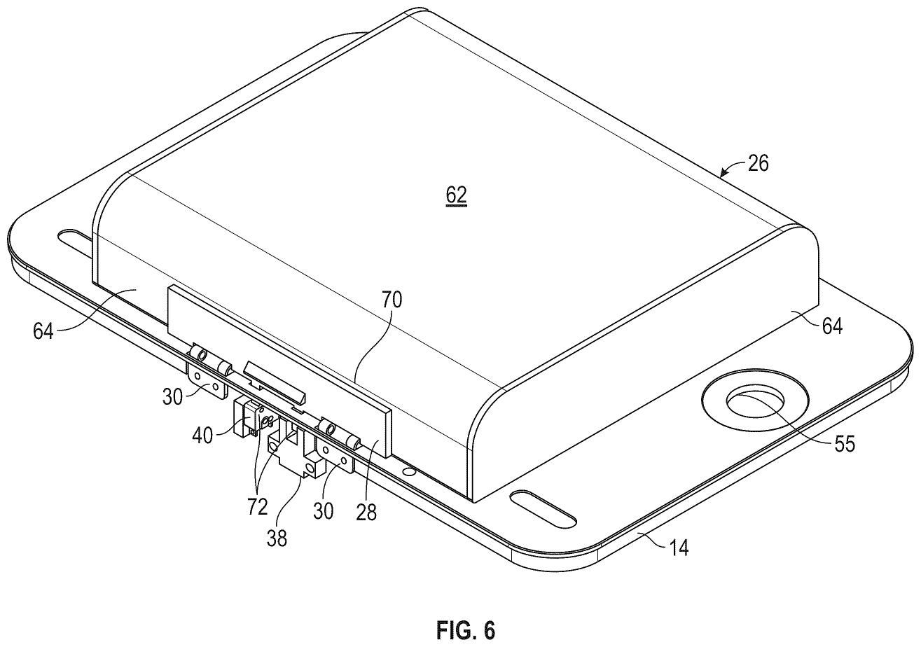

FIG. 6 is a rear perspective view of the lid 26 connected to the side plate 13. The rear wall 64 is received between and secured to the spaced-apart hinge plates 70. A portion of each of the hinges 30 is also received between and secured to the spaced-apart hinge plates 70. The hinges 30 are also secured to the side plate 13.

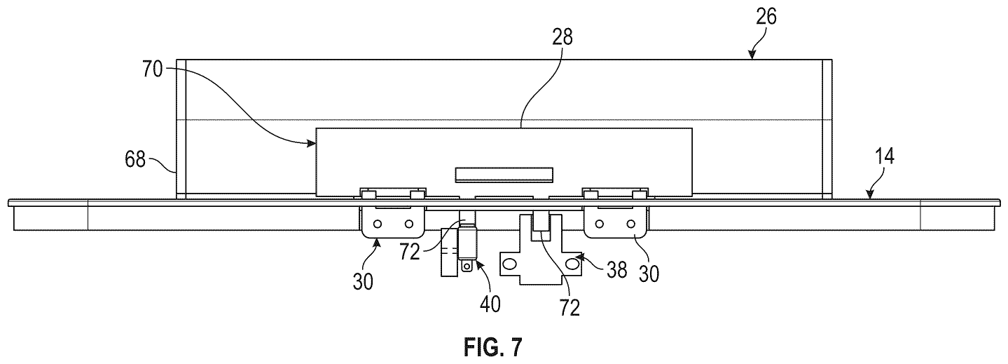

Referring to FIGS. 6 and 7, the projections 72 are aligned with the photoelectric sensor 38 and the miniature switch 40 such that when the lid 26 is opened, the projections 72 pivot upward and deactuate the photoelectric sensor 38 and the miniature switch 40. For example, the photoelectric sensor 38 and the miniature switch 40 may be configured to be deactuated when the lid 26 is opened approximately five degrees or some other amount which would still prohibit a user's finger from entering under the lid 26. As will be explained later, the automated socket actuation device 10 will stop the motors 18 if at any time either of the photoelectric sensor 38 or the miniature switch 40 is deactuated, i.e. the lid 26 is opened approximately five degrees or more.

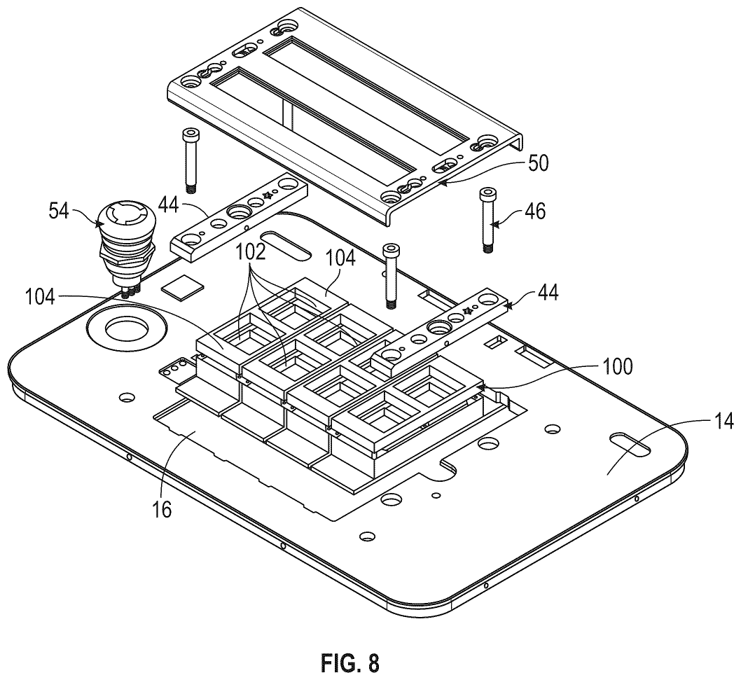

FIG. 8 is an exploded view of the top plate 14 and pressure plate 50 with a plurality of sockets 100 installed on the programmer site 16. The sockets 100 include bearing surfaces 104 which need to be pressed down to open the sockets 100 at the sites 102 to permit a device to be placed and removed. Releasing the sockets 100 causes them to close on the devices, such as for programming. Such sockets are known.

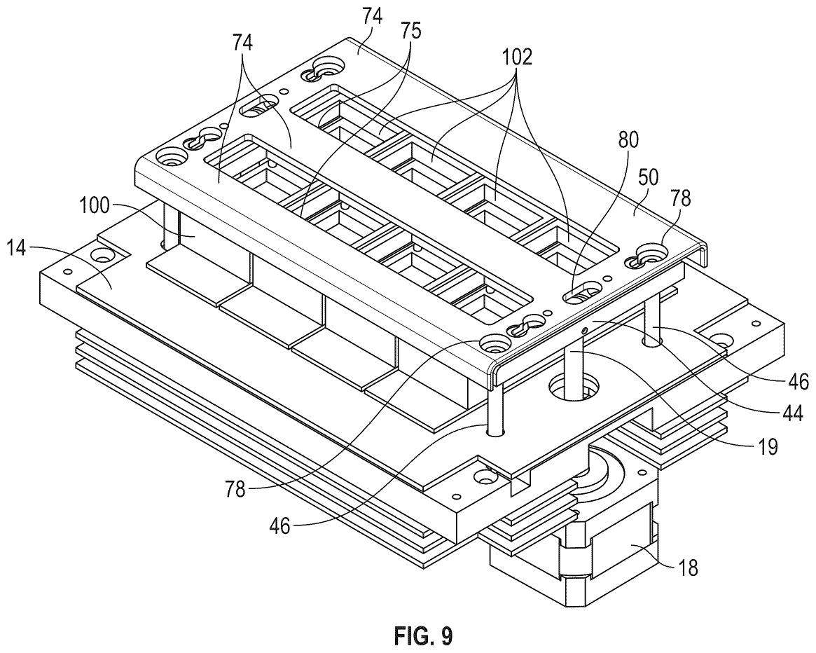

As shown in the assembled view of FIG. 9, the plurality of bar portions 74 align with the bearing surfaces 104 and the elongated openings 75 align with the sites 102. Each shaft 19 is threaded into the threaded aperture 84 of the T-post 44 and aligned with the aperture 80 in the pressure plate 50 (so the shaft 19 can pass freely through the apertures 80 when the motors 18 pull the pressure plate 50 down).

The T-posts 44 are secured to the pressure plate 50. The guides 46 are received through the guide apertures 78, with the heads of the guides 46 captured by the shoulders in the countersunk apertures 82 in the T-posts 44. The guides 46 are then threaded into the top plate 14. The guides 46 thus limit the upward travel of the T-posts 44 and pressure plate 50 and guide them in a strictly vertical path. The T-posts 44 and guides 46 both ensure ESD safe conditions.

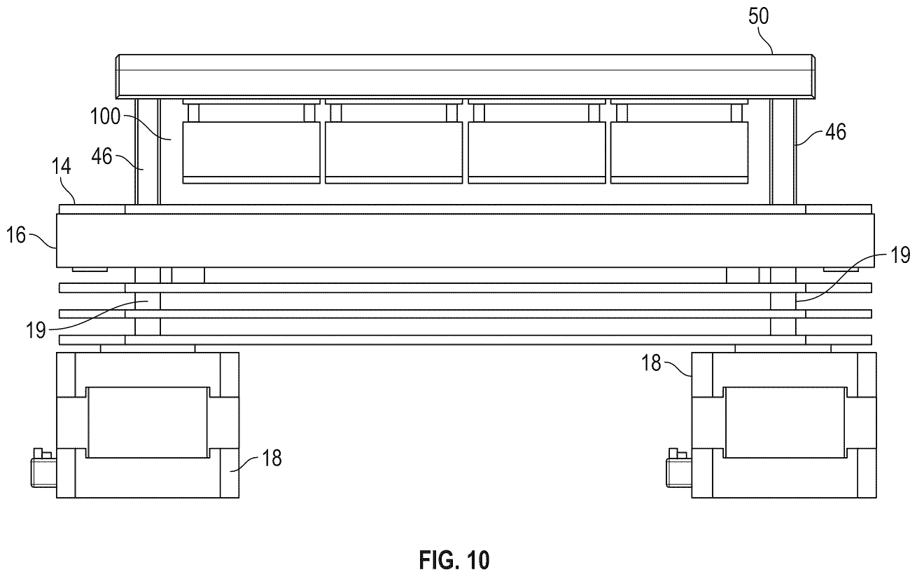

FIG. 10 is a side view of the assembly of FIG. 9.

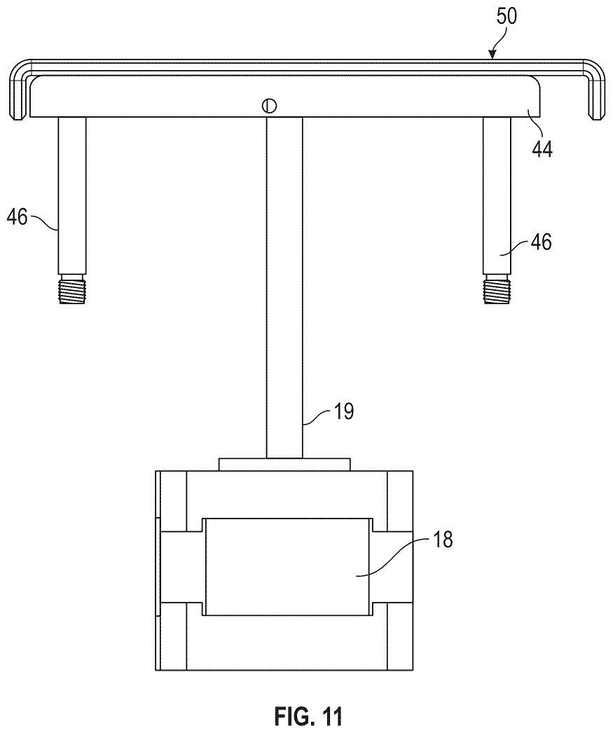

FIG. 11 is an end view of a partial assembly of the pressure plate 50 secured to the T-post 44. The other T-post 44 would be on the other side of the pressure plate 50. The T-post 44 captures the guides 46 to limit the upward travel of the pressure plate 50 and T-post 44 and to guide the pressure plate 50 and T-post 44 in a strictly vertical path. Again, the shafts 19 of the motors 18 are threaded to the T-posts 44 such that rotation of the shafts 19 by the motors 18 causes the T-posts 44 to travel up or down. The motors 18 are preferably equipped with encoders fed to the controller, such that the position of the pressure plate 50 is precisely controlled.

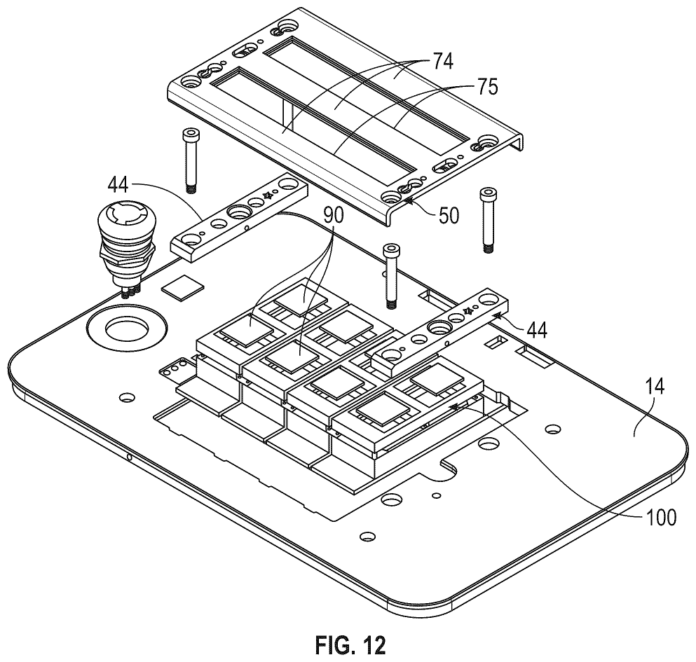

FIG. 12 is an enlarged, partially exploded view of the top plate 14 and the pressure plate 50 with devices 90 in the sites 102 of the sockets 100.

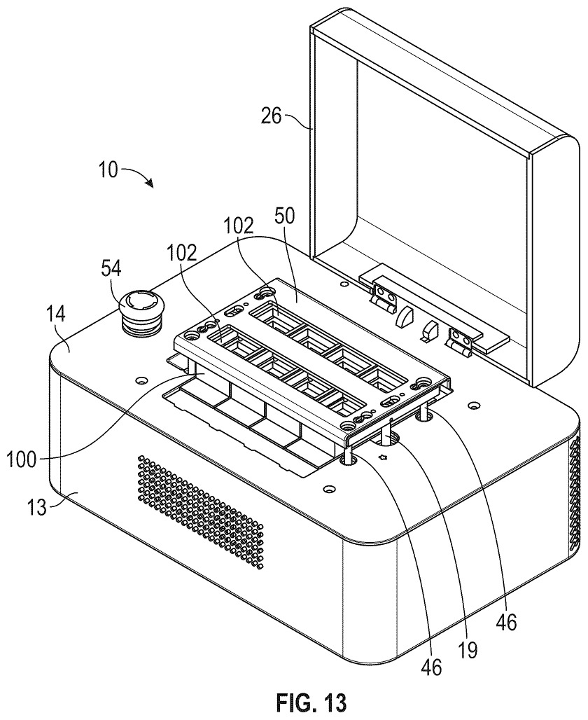

FIG. 13 is a perspective front view of the assembled automated socket actuation device 10 with the lid in the open position. The lower edge of the side plate 13 is secured to a periphery of the bottom plate 12 (not visible). The top plate 14 is secured to an upper edge of the side plate 13. The guides 46 (two visible) project through the top plate 14. The shafts 19 (one visible) project through the top plate 14 and are connected to the pressure plate 50 via a threaded connection (via the t-posts 44, not visible).

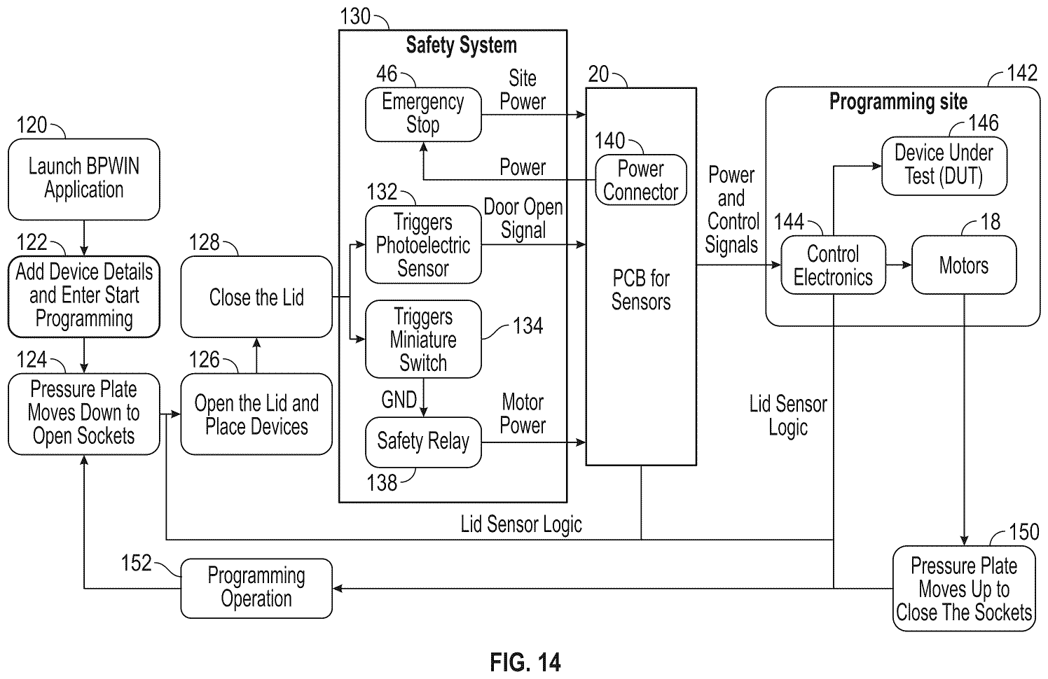

FIG. 14 is a schematic of the operation of the automated socket actuation device 10. In step 120, the user turns on the application on a computer controlling the hardware described herein. The computer includes at least one processor, at least one non-transient computer readable storage which stores data and instructions, which when executed by the at least one processor cause the automated socket actuation device 10 to perform the functions described herein.

In step 120, the user enters (or loads) device details into the computer and enters “start programming.” In response, in step 124, the computer controls the motors 18 to actuate. When the shafts 19 rotate, the threads on the shafts 19 engage the threaded apertures 84 of the T-posts 44 to draw the T-posts 44 and the pressure plate 50 down. The plurality of bar portions 74 of the pressure plate 50 press down on the bearing surfaces 104 of the sockets 100, thereby opening the sockets 100. In step 126, the user opens the lid 26 and places the devices 90 in the sites 102. In step 128, the user closes the lid 26.

The safety system 130 includes the photoelectric sensor 38 and miniature switch 40. In step 132, the photoelectric sensor 38 is actuated by the lid 26 closure. In step 134, the miniature switch 40 is actuated by the lid 26 closure. Both of these are required in order for the motors 18 to operate.

Deactuation of the miniature switch 40 by a lid 26 opening removes a ground signal from the miniature switch 40 to the safety relay 56. The safety relay 56 in turn disconnects the motors 18 from power. In other words, no matter what else happens, if the miniature switch 40 is deactuated by a lid 26 opening, the motors 18 will not run and if they are running, they will immediately stop due to loss of power.

The signal from the photoelectric sensor 38 is also sent to the PCB 20, which will also switch off the motors 18 if the photoelectric sensor 38 detects that the lid 26 is open more than a threshold amount (e.g. five degrees).

Additionally, the emergency stop button 54 can also independently send a signal to a power connector 140 on the PCB 20 to shut off power to the motors 18.

At the programming site 142, power and control signals are received by control electronics 144, which sends appropriate signals to the device 90 under test 146 and to the motors 18. When the motors 18 are actuated again with the devices 90 in place, the pressure plate 50 moves up to permit the sockets 100 to close in step 150. The devices 90 are then programmed in step 152.

At the conclusion of programming, the pressure plate 50 is again moved down by the motors 18 in step 124 (again, the motors 18 will be interrupted at any time if the lid 26 is opened or the emergency stop button 54 is pressed—and the motors 18 will resume upon lid 26 closure). The user can then open the lid in step 126 to remove the programmed devices and replace them with new devices to be programmed and the process repeats.

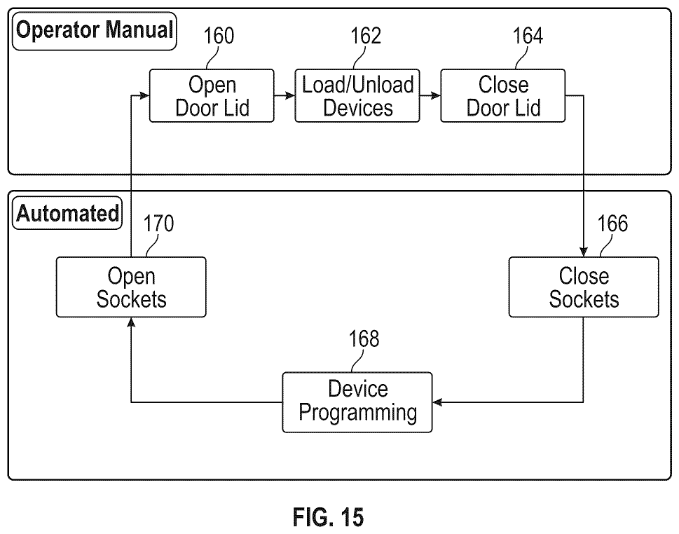

FIG. 15 is a higher-level flowchart emphasizing the user's operations versus steps performed by the automated socket actuation device 10. In step 160, the user opens the lid 26 and then loads new devices 90 (after unloading any programmed devices 90 present in the sockets 100) in step 162. The user closes the lid 26 in step 164. In step 166, the automated socket actuation device 10 closes the sockets 100 and then initiates programming in step 168. The automated socket actuation device 10 then opens the sockets 100 in step 170 and the process returns to the user opening the lid 26 in step 160.

The motors 18 (or other actuators) automatically adjust their open position based on the physical dimension of the socket 100 being opened. This automatic sensing function does not require any adjustment or teach operation. The sockets 100 can be changed rapidly when the programmer is going to be utilized to program a different integrated circuit. No tools are required to change over the programmer from one IC to another. The socket 100 has a predefined value that is programmed in the socket module definition file. So every socket 100 has its travel distance for actuation. When the socket 100 is placed, the software knows the travel distance. The motors 18 move the travel distance, making the t-post 44, along with the pressure plate 50 move up/down that closes/open sockets. The motors 18 have closed-loop feedback that keeps checking the error in the motion using encoders (there are many criteria like no lopsided, no major delay in step reaction on the motor, etc). This prevents socket damage and also if something hard got stuck in between. The procedure makes it easy to change sockets 100 with no additional teach tools, safety precautions, etc. This way sockets 100 are opened to exactly as recommended by the socket vendor and company, increasing the life of sockets and reducing the risk of device damage while placing.

Alternatively, the motors 18 could be replaced by other types of actuators. For example, pneumatic actuators could actuate the sockets. The pneumatic actuators would also be interrupted when the lid 26 is open, as above.

In accordance with the provisions of the patent statutes and jurisprudence, exemplary configurations described above are considered to represent a preferred embodiment of the invention. However, it should be noted that the invention can be practiced otherwise than as specifically illustrated and described without departing from its spirit or scope. Alphanumeric identifiers on method steps are for the purpose of ease of reference in dependent claims and do not signify a required order of performance unless otherwise specified.

What is claimed is:

1. A socket actuation device comprising:
a pressure plate configured to contact at least one socket; and
at least one actuator configured to cause the pressure plate to press down on the at least one socket.

2. The socket actuation device of claim 1 wherein the pressure plate includes a plurality of bar portions defining a plurality of elongated openings through which devices can be placed into sites in the at least one socket.

3. The socket actuation device of claim 1 further including a lid movable between an open position in which the at least one socket can be accessed by a user and a closed position preventing access to the at least one socket by the user.

4. The socket actuation device of claim 3 further including at least one switch configured to inhibit the at least one actuator when the lid is not in the closed position.

5. The socket actuation device of claim 4 wherein the at least one switch includes a photoelectric sensor.

6. The socket actuation device of claim 5 wherein the at least one switch further includes a miniature switch.

7. The socket actuation device of claim 6 wherein the at least one switch further includes a relay connected to the miniature switch and wherein the relay disconnects the at least one actuator from power based upon a state of the miniature switch.

8. The socket actuation device of claim 6 wherein the at least one actuator is stopped if either the miniature switch or the photoelectric sensor indicates that the lid is not in the closed position.

9. The socket actuation device of claim 1 wherein the at least one actuator includes at least one electric motor.

10. The socket actuation device of claim 9 wherein the at least one electric motor includes a threaded shaft, wherein rotation of the threaded shaft moves the pressure plate.

11. A method for programming at least one device including:
a) pressing at least one socket in a first direction with a pressure plate;
b) after step a), receiving a device in each of at least one site in the at least one socket;
c) after step b), moving the pressure plate in a second direction, opposite the first direction;
d) after step c), programming the device in each site in the at least one socket; and
e) after step d), moving the pressure plate in the first direction to open the at least one socket.

12. The method of claim 11 wherein step a) includes activating at least one actuator.

13. The method of claim 11 wherein step a) includes activating at least one electric motor having a threaded shaft engaging the pressure plate.

14. The method of claim 11 further including:
f) receiving an indication that a lid is in a closed position;
wherein the lid prevents a user from accessing the at least one socket when the lid is in the closed position and permits a user to access the at least one socket when the lid is in an open position, wherein step a) is performed based upon step f).

15. The method of claim 14 wherein step f) includes receiving a signal from a photoelectric sensor and receiving a signal from a contact switch.

16. The method of claim 11 further including:
f) after step e), removing the device from each of the at least one site in the at least one socket.

17. A socket actuation device comprising:
a housing having a bottom plate, a side plate secured to the bottom plate, and a top plate secured to the side plate;
at least one motor within the housing, each at least one motor including a threaded shaft extending upward through the top plate;
a programmer site secured to the top plate;
a pressure plate secured to the programmer site and configured to contact at least one socket, each threaded shaft connected to the pressure plate via a threaded connection; and
a lid pivotably secured to the housing and pivotable between a closed position in which access to the programmer site is prevented and an open position in which access to the programmer site is permitted.

18. The socket actuation device of claim 17 wherein the pressure plate includes a plurality of bar portions defining a plurality of elongated openings through which devices can be placed into sites in the at least one socket.

19. The socket actuation device of claim 18 further including at least one switch configured to inhibit the at least one motor when the lid is not in the closed position.

20. The socket actuation device of claim 19 wherein the at least one switch includes a photoelectric sensor and a contact switch, wherein the at least one motor is inhibited if either the contact switch or the photoelectric sensor indicates that the lid is not in the closed position.
